(19) United States
(12) Patent Application Publication
(10) Pub. No.: US 2016/0238452 A1
(43) Pub. Date: Aug. 18, 2016

(54) PYROELECTRIC REFERENCE DEVICE FOR MICRO-POWER HARVESTING AND SENSOR APPLICATIONS

(71) Applicants: Shuza Binzaid, San Antonio, TX (US); Ruyan Guo, Helotes, TX (US); Amar S. Bhalla, Helotes, TX (US); Sandeep Kumar Bomthapalli, Farmington Hills, MI (US)

(72) Inventors: Shuza Binzaid, San Antonio, TX (US); Ruyan Guo, Helotes, TX (US); Amar S. Bhalla, Helotes, TX (US); Sandeep Kumar Bomthapalli, Farmington Hills, MI (US)

(21) Appl. No.: 14/687,884

(22) Filed: Apr. 15, 2015

Related U.S. Application Data
(60) Provisional application No. 61/979,675, filed on Apr. 15, 2014.

(51) Int. Cl. G01J 5/02; H03F 3/50; H03K 5/156

(52) U.S. Cl. CPC G01J 5/02; H03K 5/1565; H03F 3/505; G01J 2005/0048

(57) ABSTRACT

A pyroelectric reference device comprising an equivalent electronic circuit that produces the similar electrical characteristics of a pyroelectric material sample device, under discrete thermal conditions in laser energy lab setup, is disclosed herein. The device presented here facilitates running experiments without the need of special equipment and/or setups using the real pyroelectric device in thermal radiation environments for harvesting micro power energy.

### CROSS-REFERENCE TO RELATED APPLICATIONS

This application claims the benefit under Title 35 United States Code §119(e) of U.S. Provisional Patent Application Ser. No. 61/979,675; Filed: Apr. 15, 2014, the full disclosure of which is incorporated herein by reference.

### STATEMENT REGARDING FEDERALLY SPONSORED RESEARCH OR DEVELOPMENT

This invention was made with government support under grants ECCS-#1002380 and DMR-#0844081 awarded by the National Science Foundation. The government has certain rights in the invention.

### THE NAMES OF THE PARTIES TO A JOINT RESEARCH AGREEMENT

Not applicable

### INCORPORATING-BY-REFERENCE OF MATERIAL SUBMITTED ON A COMPACT DISC

Not applicable

### SEQUENCE LISTING

Not applicable

### FIELD OF THE INVENTION

The present invention generally relates to a device and method of use directed to microelectronics. More specifically, the present invention relates to a device and method of use for an electronic equivalent to a pyroelectric material sample device with similar electrical characteristics.

### BACKGROUND OF THE INVENTION

Without limiting the scope of the disclosed device and method, the background is described in connection with a novel device and approach to provide an electronic equivalent to a pyroelectric material sample device by providing similar electrical characteristics. That is circuits, devices, and systems that replace a pyroelectric material for harvesting energy that requires expensive lab setups.

It has been a challenge to develop a suitable test setup for pyroelectric device characterizations, unlike the piezoelectric device. Test setups requires powerful concentrated and focused light sources, often lasers in discrete mode and sophisticated control instruments for optimizing the pyroelectric effects [13, 14]. These setups require a number of expensive instruments for measurements and characterizations.

Pyroelectricity as a phenomenon has been known for twenty-four centuries, Pyroelectric materials convert changes in absolute temperatures into electrical energy, unlike thermoelectric which need a gradient of temperature across the material [7]; Pyroelectric materials require temporal changes (time vs. spatial variation). The pyroelectric effect can be used for harvesting thermal energy during temperature increases (heating) and decreases (cooling) and thus creating a difference in temperature of surfaces of the pyroelectric crystals [3]. The pyroelectricity is the ability of crystals to generate a temporary voltage and current when there is difference of temperature. The change in temperature slightly modifies portions of the atoms within the crystal structure of the crystal causing a polarization. The change in polarization, strictly dependent on time, gives rise to voltage across the crystal. If the temperature stays unchanged based on the material's critical time, then pyroelectric voltage gradually disappears due to internal charge leakage.

Pyroelectricity can be visualized with a Heckmann diagram [5], as shown in FIG. 1. Changes in temperature causes change in electric displacement (Primary pyroelectric effect). Changes in thermal expansion causes a strain that alters the electric displacement (secondary pyroelectric effect).

While the aforementioned devices and approaches may fulfill their unique purposes, none of them fulfill the need for a practical and effective means for providing a pyroelectric reference device without requiring substantial setups and many pieces of equipment.

The present invention therefore proposes a novel device and method of use for providing a pyroelectric reference device setup that overcomes the shortcomings of the prior art.

### BRIEF SUMMARY OF THE INVENTION

The present invention, therefore, provides for an electronic equivalent circuit and hardware module that produces similar electrical characteristics of a pyroelectric material sample device. A solution is presented to resolve issues of an electronic module to replace a pyroelectric material for harvesting energy in an expensive lab setup.

In order to maintain circuit compactness and to reduce the number of components, certain embodiments of this invention may be designed with the discrete clock design principle using low power logical switching gates. This design principle enables to resolve power consumption concerns and facilitated to use the low-power DC supplies such as button-cell or small rechargeable batteries.

In an embodiment, the claimed invention may be compacted on a PCB fitted in about 2×3×0.7 inch polymer package including a separate battery chamber while weighing less than 3 ounces. Having such dimensions, the invention may be structured to have minimum setting options that can be placed internal to the package, making it a pocket carrying device operating at fixed-mode.

Certain embodiments of the device maintain locked preset parameters for duty cycle, voltage current, and energy levels that can only be changed and reset with internal access by experienced engineers. With the parameters preset properly, the mixed-signal conversion completes a single analogous pyroelectric signal at its output. Thus it becomes a reference module and very suitable for single-batch devices of pyroelectric material with precise characteristics. Modification of these parameters may be carried out by a technician or engineer in the backend production enabling quick batch monitoring and controlling the mass-production quality.

Some applications of the disclosed invention may include using a pyroelectric emulator system to preset the parameters of the module. The module can be preset or preprogrammed by the front-end design engineers who can interpret the simulation results and also analyze the pre-production pilot or control lots of pyroelectric devices. The invention may serve as a device/module for applications of quick reference purposes in high yield production environments. A mass-production facility can have a number of these devices/modules to monitor devices based on the class and type of batches being produced.

In embodiments the device/module may be programmed with various pre-set parameters that are capable of being toggled via a switch or other interface or control device on the module. In embodiments the invention will comprise of a discrete clock driver configured for ultra-low power consumption while performing mixed-signal conversion. In embodiments the output of the invention are pyroelectric locked duty cycle analog signals.

In the device is comprised of a pyroelectric equivalent circuit. In embodiments a pyroelectric equivalent circuit is comprised of a pyroelectric element with a current source and an internal capacitor. In embodiments the current source is in parallel with the internal capacitor.

In embodiments the pyroelectric element is connected in parallel to an external capacitor and a resistor. In embodiments a voltage is generated at the output of the pyroelectric element. In embodiments the current from the pyroelectric current is proportional to the rate of change of the temperature, and the power output of the pyroelectric element can be determined by using the output voltage and the equivalent resistance connected parallel to the element.

The signal information through the load resistance of the pyroelectric equivalent circuit can be in the form of either voltage or current. In embodiments low currents supplied by a high impedance source will be converted to low impedance voltage signals. In embodiments this conversion will be performed by read-out circuitry.

In embodiments the read-out circuitry is comprised of pre-amplifier with high-impedance input. In embodiments the read-out circuitry may be a voltage mode follower. In other embodiments the read-out circuitry may be a current mode amplifier. In yet other embodiments the read-out circuitry may be a source follower with integrated gain stage.

In certain embodiments the source follower with integrated gain stage may be a combination of both voltage mode follower and a current mode amplifier. In embodiments twin channel pyroelectric element with two load resistors, two FET's and two source resistors are combined in one package. This design offers low output impedance with a high integrated gain stage, offering with low level inputs using a simple pre-amplifier circuit with two FET's.

Certain embodiments of the invention are directed toward an electronic pyroelectric module. In some embodiments the pyroelectric module is comprised of a power supply, a pulse generator, a current push-pull amplifier, digital voltage I/O and signal conditioning circuit components.

In embodiments the signal conditioning circuit is a charge compensation circuit.

In embodiments the pyroelectric module power supply is a ripple-free DC power supply. In embodiments the power supply is a battery. In embodiments the module is small enough to fit into the pocket of a lab coat or other piece of clothing.

In embodiments the battery is a small battery no larger than 75 mm×75 mm×75 mm. In embodiments the battery is selected from a group of commercially available sizes including, but not limited to: AAA, AA, C, D, 9 volt. In a preferred embodiment the batteries are A36. In embodiments the batteries are rechargeable.

In embodiments the pulse generator circuit is comprised of two comparator amps, an R-S flip-flop, push-pull drive-amp and a RC network. In a preferred embodiment the pulse generator circuit is comprised of a discrete clock driver for ultra-low power consumption purposes.

In embodiments voltage and current is controlled internally of the module, so the module cannot be damaged due to shorted output. In embodiments the module can run in nano- and micro-power ranges. In embodiments the electrical characteristics can be preset internally to obtain matched electrical characteristics of a particular type of pyroelectric material device. In embodiments the module can be configured to replace the matched pyroelectric material device where such device application is required.

In embodiments the pyroelectric module can be configured to be used as a reference apparatus for a pyroelectric device. In certain embodiments preset electrical characteristics remain unchanged under normal operating conditions and thus become reference apparatus to a particular batch or type of pyroelectric devices. In some embodiments the pyroelectric module can be preset to match V(t), I(t) and Q(t) that are crucial electrical characteristics of a particular pyroelectric device. In some embodiments the pyroelectric module can be used as reference electrical signal driver matching for a particular pyroelectric device that can be used as energy harvesting or sensing purposes.

Other embodiments of the invention are discussed throughout this application. Any embodiment discussed with respect to one aspect applies to other aspects as well and vice versa. Each embodiment described herein is understood to be embodiments that are applicable to all aspects of the invention. It is contemplated that any embodiment discussed herein can be implemented with respect to any device, method, or composition, and vice versa. Furthermore, systems, compositions, and kits of the invention can be used to achieve methods of the invention.

In summary, the present invention discloses an improved device and method of use to microelectronics. More specifically, the present invention relates to a device and method of use for an electronic equivalent to a pyroelectric material sample device with similar electrical characteristics.

### BRIEF DESCRIPTION OF THE SEVERAL VIEWS OF THE DRAWINGS

For a more complete understanding of the features and advantages of the present invention, reference is now made to the detailed description of the invention along with the accompanying figures in which:

FIG. 1 is a Heckman diagram in accordance with embodiments of the disclosure;

FIG. 2 is an equivalent pyroelectric circuit of the pyroelectric reference device in accordance with embodiments of the present disclosure;

FIG. 3 is a source follower with integrated gain stage of the pyroelectric reference device in accordance with embodiments of the present disclosure;

FIG. 4 is a PSPICE equivalent pyroelectric circuit of the pyroelectric reference device in accordance with embodiments of the present disclosure;

FIG. 5 illustrates applied signals to gates M1 and M2 switching NMOS transistors of the pyroelectric reference device in accordance with embodiments of the present disclosure;

FIG. 6 is a voltage and current response of the pyroelectric circuit model of the pyroelectric reference device in accordance with embodiments of the disclosure;

FIG. 7 is a block diagram of the equivalent pyroelectric device test hardware of the pyroelectric reference device in accordance with embodiments of the disclosure;

FIG. 8 is a 700 mV and 33% rise of duty-cycle at no load of the pyroelectric reference device in accordance with embodiments of the disclosure;

FIG. 9 is a 700 mV at max-load condition of 100% rise of duty-cycle of the pyroelectric reference device in accordance with embodiments of the disclosure;

FIG. 10 is a 700 mV at overload condition of 100% rise of duty-cycle of the pyroelectric reference device in accordance with embodiments of the disclosure;

FIG. 11 is a pocket pyroelectronic electronic module of the pyroelectric reference device in accordance with embodiments of the disclosure;

FIG. 12 is an output of the oscilloscope during a no load test of the pocket pyroelectric electronic module of the pyroelectric reference device in accordance with embodiments of the disclosure;

FIG. 13 is a test setup of the electronic pyroelectric module with a 2× voltage booster to charge a capacitor of the pyroelectric reference device in accordance with embodiments of the disclosure;

FIG. 14 is an application setup for a micro power wireless device powered by a pyroelectric reference device having a 2× voltage booster and rechargeable battery in accordance with embodiments of the disclosure.

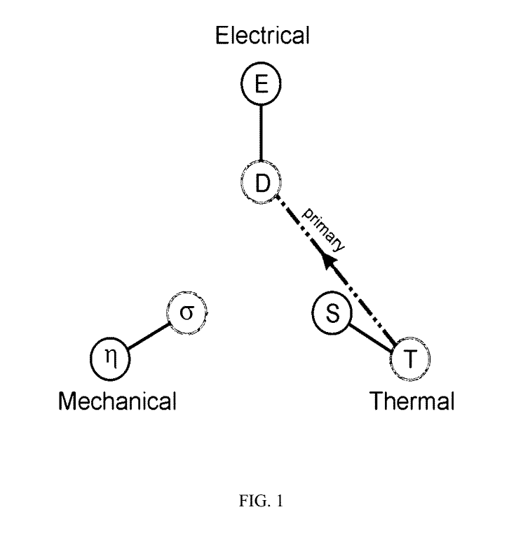

### DETAILED DESCRIPTION OF THE INVENTION

Disclosed herein is an improved device and method of use for an electronic equivalent circuit and hardware module that produces similar electrical characteristics of a pyroelectric material sample device. The numerous innovative teachings of the present invention will be described with particular reference to several embodiments (by way of example, and not of limitation).

This disclosure presents the electronic equivalent simulator module for pyroelectric materials. As pyroelectric materials are considered to be an energy source, the study of electrical combinational circuit was made and developed a simulator model for micro power energy harvesting.

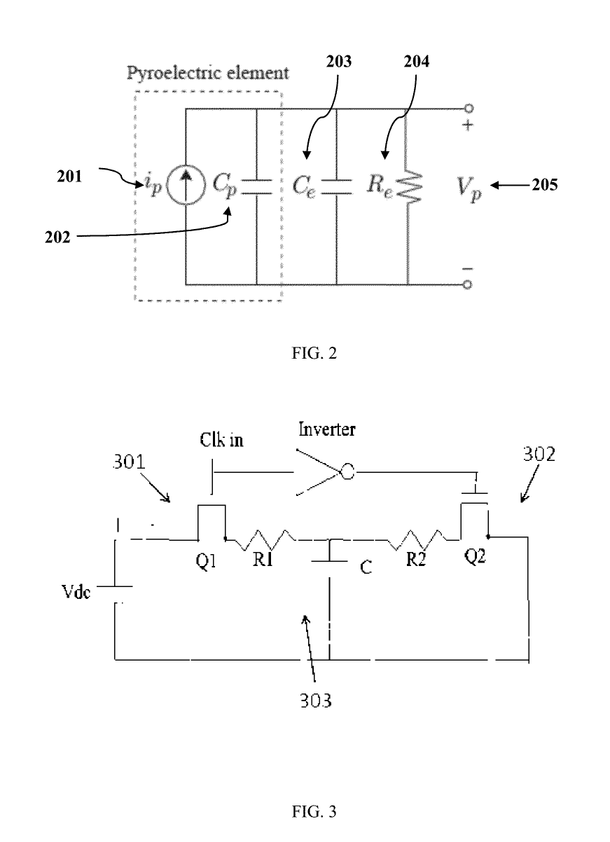

Electrical model of a pyroelectric material is modeled as a simple pyroelectric equivalent circuit. The material is considered to exhibit the pyroelectric effect when a change in the material's temperature with respect to time which results in the production of electrical charge. A simple model of the pyroelectric equivalent circuit [1], as shown in FIG. 2 comprises of a pyroelectric element with a current source and an internal capacitance cₚ.

In practice, the detectors current from the pyroelectric element is proportional to the rate of change of temperature [2].

$${i}_{p} ( t ) = {P}^{*} A \frac{d T ( t )}{d t}$$

Where, P* is the pyroelectric coefficient, ‘A’ is the electrode surface area and T(t) denotes temperature with respect to time.

FIG. 2 shows an equivalent pyroelectric circuit [1] where, iₚ 201 is the current source in parallel with internal capacitance Cₚ 202, Cₑ 203, and Rₑ 204 is the external capacitor and resistor connecting parallel to the pyroelectric element, where Vₚ 205 is the output voltage generated at the output of the pyroelectric element.

The power output of the pyroelectric element can be determined by using the output voltage and the equivalent resistance connected parallel to the element.

$$P ( t ) = \frac{{v}^{2} ( t )}{{R}_{e}}$$

$$Δ V = \frac{A \cdot {P}^{*} \cdot Δ T}{{C}_{d}}$$

Where, v(t) is the output voltage and Rₑ is the equivalent electrical resistance.

ΔV Is the change in the output voltage, ΔT is the change in the temperature, A is the electrode surface area, P* is the Pyroelectric coefficient and C_{d} is the equivalent electric capacitance.

Equivalent Circuitry for Pyroelectric Signal and Energy

The signal information through the load resistance of the pyroelectric equivalent circuit can be voltage or the current. These signals have extremely low currents supplied by a high impedance source that has to be converted to produce a more practical low impedance voltage signals. The conversion is done through the read-out circuitry.

Read-Out Circuitry for Pyroelectric Signal Energy

Read-out circuitry is integrated with the pyroelectric circuit consisting of a pre-amplifier with high-impedance input. There are three read-out circuits for pyroelectric signals with pre-amplifier circuits, they are
Voltage mode follower.
Current mode amplifier.
Source follower with integrated gain stage.

In an embodiment, a source follower technique with integrated gain stage is utilized. The source follower with integrated gain stage is a combination of both voltage mode follower and a current mode amplifier. In this embodiment, a twin channel pyroelectric element with two load resistors, two FET's and two source resistors are combined all in one package. This design offers low output impedance with a high integrated gain stage, offering with low level inputs using a simple pre-amplifier circuit with two FET's [6], as shown in FIG. 3. The region of 301 comprises the equivalent circuit of the internal pyroelectric element for current source stage. Contained in the region of 302, equivalent external capacitance and resistance is applied during a load condition of the pyroelectric element, also shown in FIG. 2. Furthermore, in the region 303 consists of an equivalent electric capacitance, C_{d} used previously in determining ΔV.

PSPICE Modeling of an Equivalent Circuit of the Pyroelectric Device

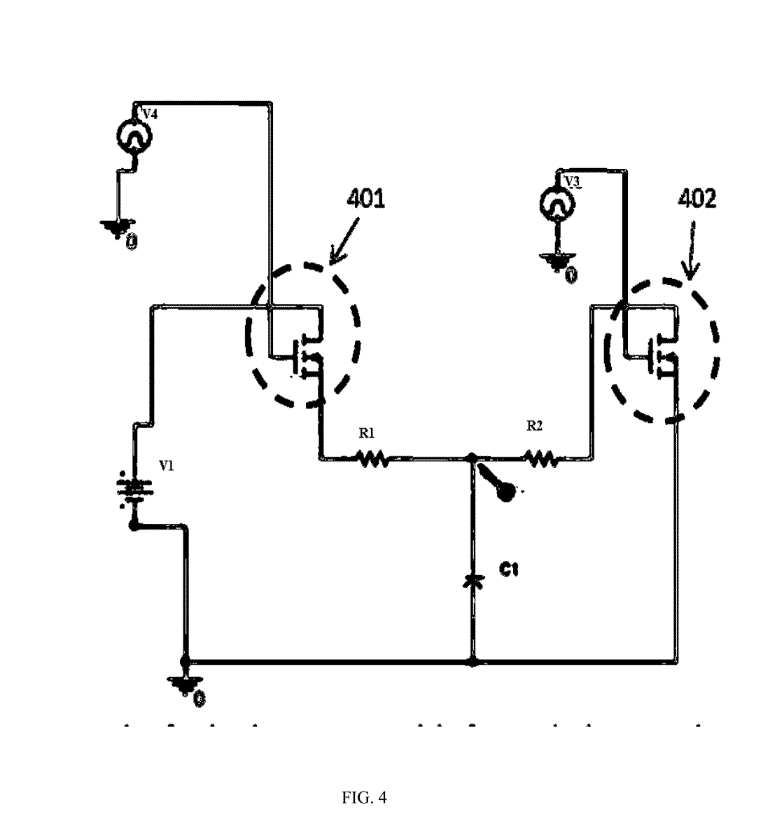

PSPICE model for pyroelectric equivalent circuit was simulated using the pyroelectric element and the source follower with integrated gain stage. The design consists of very low threshold voltage FET switches (in the region of 401 and 402) that operate with complementary trigger signals as shown in FIG. 4. The design uses the NFETs in the pyroelectric element as a voltage source which is maintained at a very low constant DC voltage. The control through the circuit is maintained through the gate of switches. The idea of the circuit is to the charge the capacitor with the help of one switch and discharge the capacitor with the other. Due to pyroelectric materials are dielectrics materials, the source resistors are modeled at a very high electrical resistance and thus current I, is very small.

The embodiment in FIG. 4 is modeled to have a 4 Hz signal across the capacitor and to have an equivalent output voltage of 900 mv and with maximum current of 28 uA. Here in this design the differences in voltages are taken as the potential differences between two electrodes of the pyroelectric material i.e. the output of the single pyroelectric device, shown in FIG. 2.

PSPICE Results from Pyroelectric Equivalent Circuit

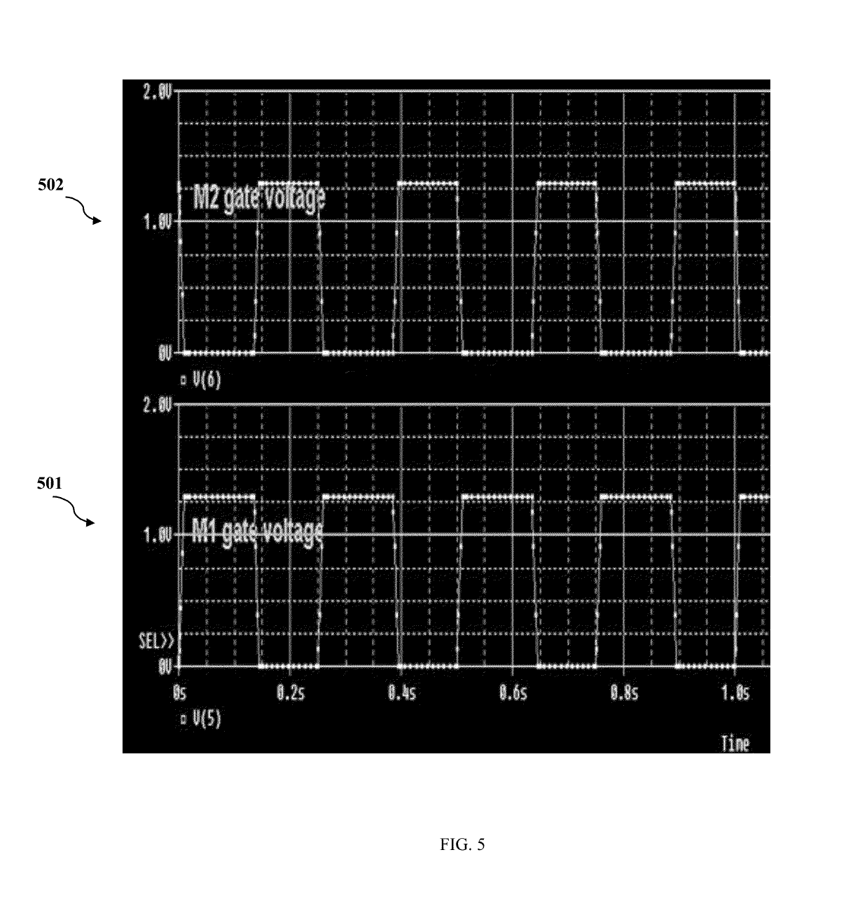

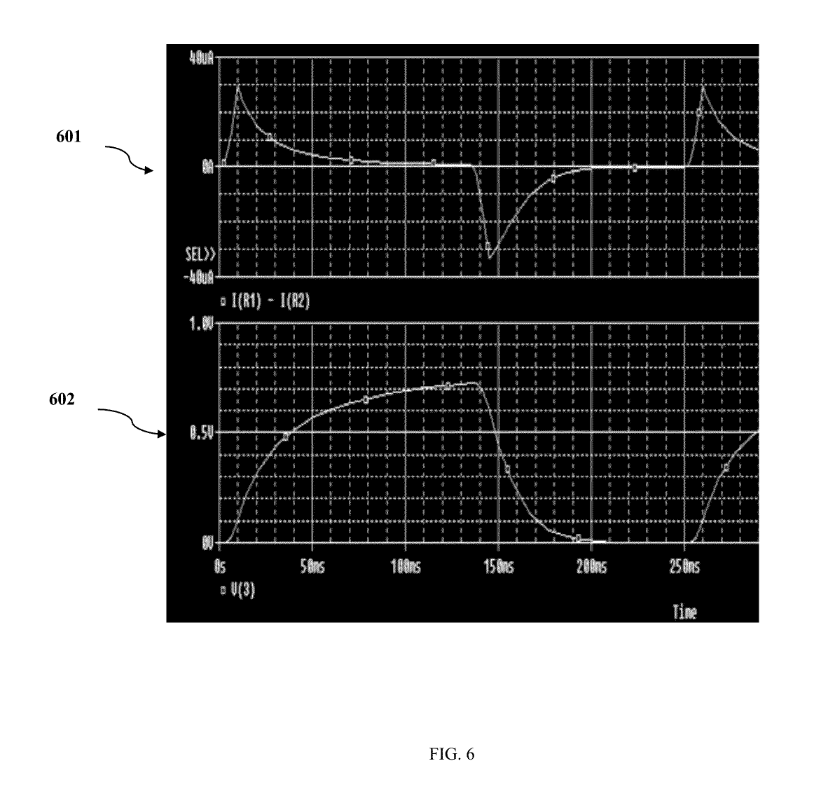

FIG. 5 and FIG. 6 show the gate voltage applied to the NFETS and the voltage and current response from the pyroelectric equivalent circuit. The results were drawn for the pyroelectric equivalent circuit, the series or parallel association of these kinds of pyroelectric cells can be clustered to increase the currents so that they form stacked structures to produce high energies. FIG. 5 shows the switching sequence of M1 501 and M2 502 and FIG. 6 shows the current 601 and voltage 602 results at the probed point of the circuit.

Hardware Design of the Electronic Pyroelectric Module

The PSPICE circuit was modeled as presented in previous sections that showed operation under ultra-low-threshold voltage; in this section is developed a hardware solution using the same electrical characteristics found in lab tests of pyroelectricity from a device. In an embodiment, the circuit is developed to be an ultra-compact hardware and equivalent circuit of a pyroelectric device.

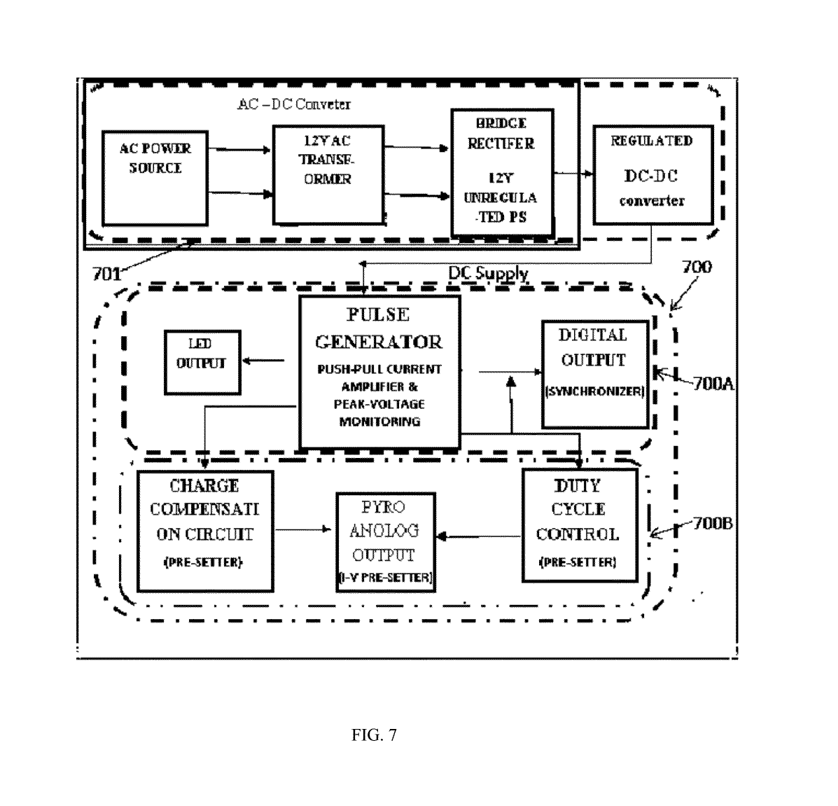

The completed device/system block diagram is shown in FIG. 7. Hardware configuration and setups are important for a pulse based (i.e. discrete laser light application in lab) pyroelectric device electronics, shown in the region of 700, consists of two parts. A pulse generator, a current push-pull amplifier, Digital voltage I/O and signal conditioning circuit components are shown in the region of 700A. The signal conditioning circuit is a charge compensation circuit and duty cycle control for both digital and analog signals are shown in the region of 700B. The practical test circuit utilizes a ripple-free DC power supply, is shown in the region of 701. The complete module is a mixed-signal system and it also has a digital LED for basic monitoring visually. The pulse generator circuit consists of two comparator amps, an R-S flip-flop, push-pull drive-amp and a RC network. The pyroelectric reference device is shown in block 700 with the optional power supply shown in block 701. The DC supply is currently set for a battery for portability. The system's main functions are dedicated to a pyroelectric device in lab and they are:
Current and voltage compensation is preset by the RC network that is internal to the system shown in the region of 700A.
Optimized frequency of a targeted pyroelectric device in the lab is preset internally of the system in the region of 700B is also a function created by RC constant.
A window of operating threshold is created between ⅓ and ⅔ of the supply voltage in the region of 700A and it also acts as a voltage follower.
Duty cycle is preset in the region of 700B (i.e. laser pulse delay and duration for optimized energy in the real lab setup) is applied to the digital pulse generation in the region of 700A of the pyroelectric hardware module.

The complete circuit is given a power supply of 5V regulated DC source that is fed from an AC-DC converter when optionally availed. In normal operation, a small battery having 3.6V is placed within the referenced device.

PSPICE Results and Circuit Verification of Hardware of the Electronic Pyroelectric Module

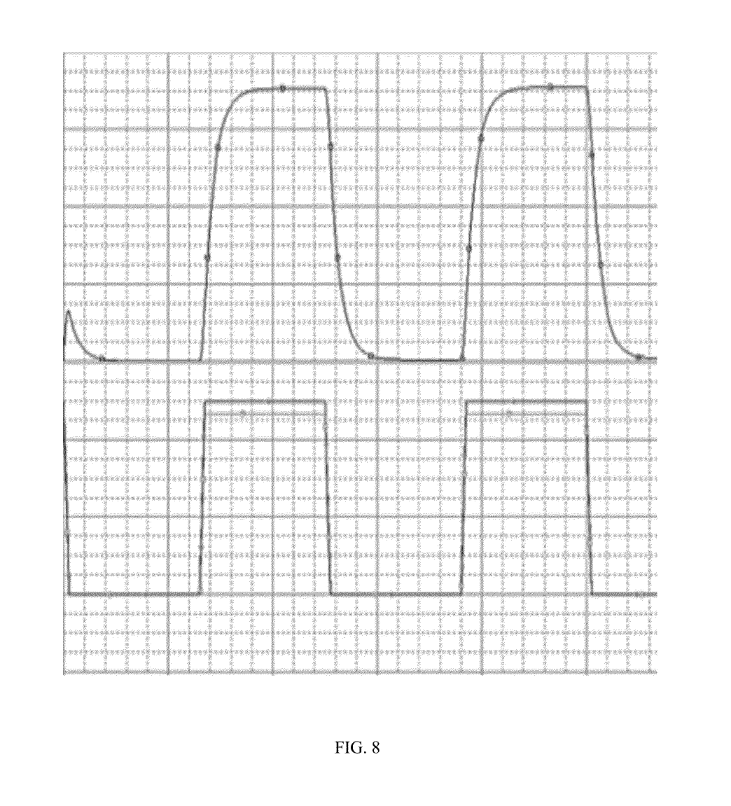

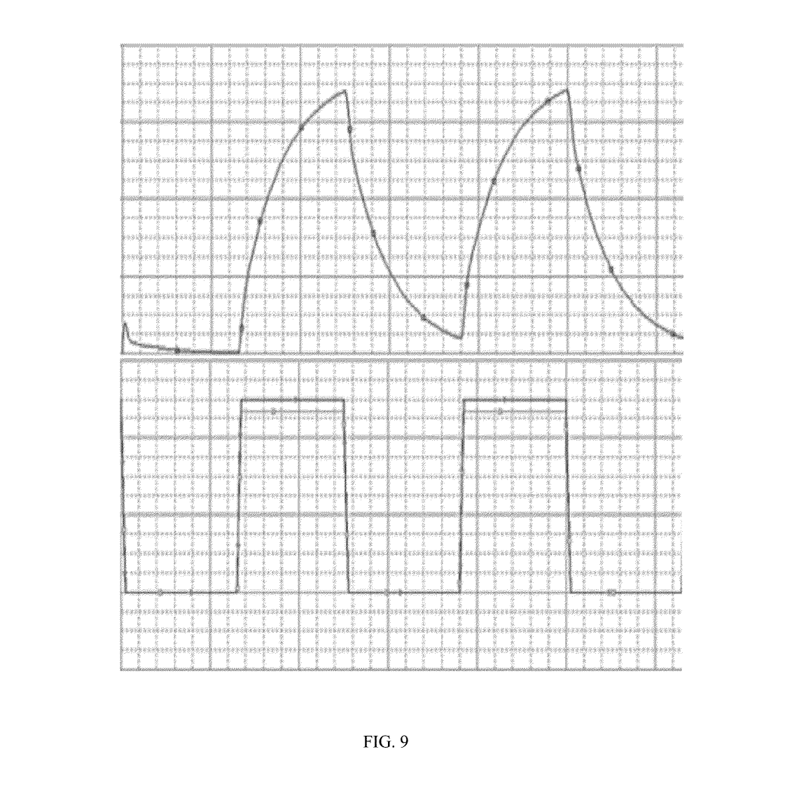

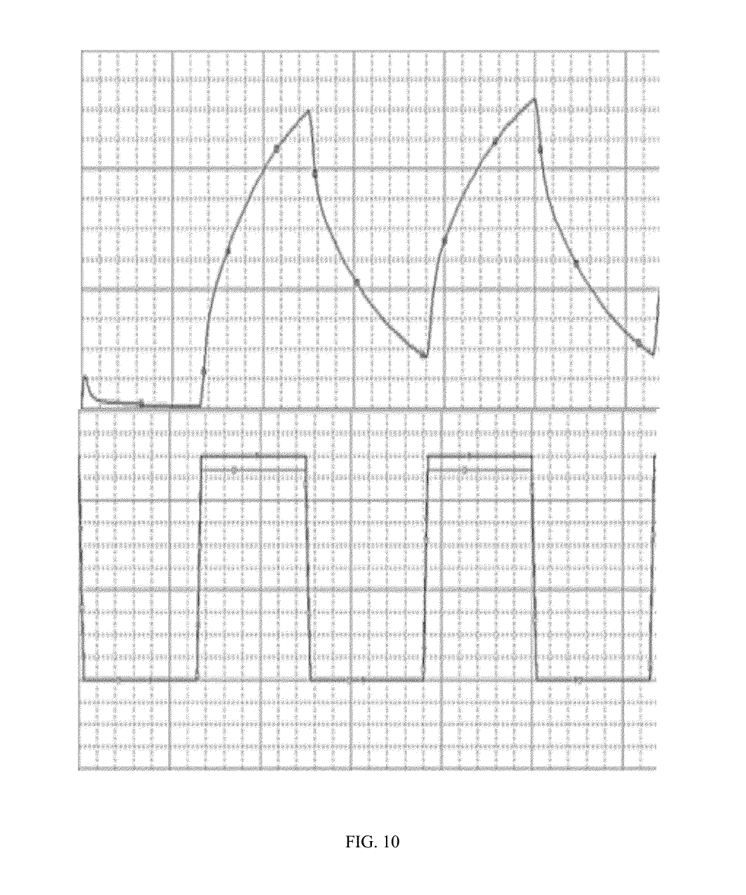

Results from PSPICE are shown in the following figures which include the loaded and unloaded condition of the pyroelectric output. In FIG. 8, the output of the compact pyroelectric module is made to have charge saturation at 33% rise of duty-cycle maintaining an output of 700 mV. By adding load to the circuit as shown in FIG. 9, the charge can be compensated at 100% rise of duty-cycle maintaining to have a same 700 mV as the output of the pyroelectric module. Similar overloaded condition is shown in FIG. 10.

### Example 1

### Ultra-Compact Pocket Electronic Module of Pyroelectric Device

Disclosed herein is an embodiment of an ultra-compact pocket electric module of an pyroelectric device. After having the AC-DC power supplied to the devised pyroelectric electronic module, the device was configured to that it could run with small batteries at various voltages as the battery voltage would go down after hours of usage. So ultra-low power CMOS circuit components were utilized for designing this pocket version of pyroelectric module. This ultra-compact electronic module has an equivalent pyroelectric circuit having the similar characteristics of the dedicated pyroelectric device at output.

Specifications of the pocket pyroelectric electronic module:
Frequency of the gyro-electric output energy signal=4.8 Hz.
Pyroelectric charge compensation=0.46 uF.
Peak output voltage=900 mV at 3.6 VDC supply.
Powered by 3 button-cell batteries type: A76.
Max output current=28 uA at 900 mV as Pyroelectric Device.
Min output current=150 nA at 225 mV as Pyroelectric Sensor.
Dimensions: 2″(L)×2″(W)×0.75″(H)
Weight: 1.1 Oz.

Voltage Booster Circuit for Testing the Micro Power Pyroelectric Pocket Module

A voltage booster circuit is used and designed for low power energy harvesting devices like energy conversion from pyroelectric materials. The voltage generated from these pyroelectric materials is relatively low which need to be boosted so that it can be used to store a small rechargeable button cell battery and thus it can be used to power up small scale RF based wireless applications. The micro power energy sources provide very low currents, for this reason a non-leakage current path voltage booster is successfully designed for additional tests of micro-power charging. This new voltage booster circuit is designed using ultra low threshold voltage active components such as diodes, transistors and ultra-low leakage-current capacitors like Tantalum capacitors. It is a non-inductive power booster.

In its simplest form, this voltage booster is a synchronous to the discrete low power signal coming from the pocket module. In practice, such a system does not work well and requires the use of additional components in order to produce good-quality output. The additional components help to eliminate spikes and ripples that can be caused during the voltage multiplication process, thus allowing the output voltage to be more useful. A voltage booster works by capturing both forward-moving voltages from the low-power signal that is modified from the discrete function to have positive and negative values to the common ground. The two captured voltages join together to become a single voltage that is multiplied by the number of booster stages. This was done on the 2× booster that produced double voltage of the incoming signal.

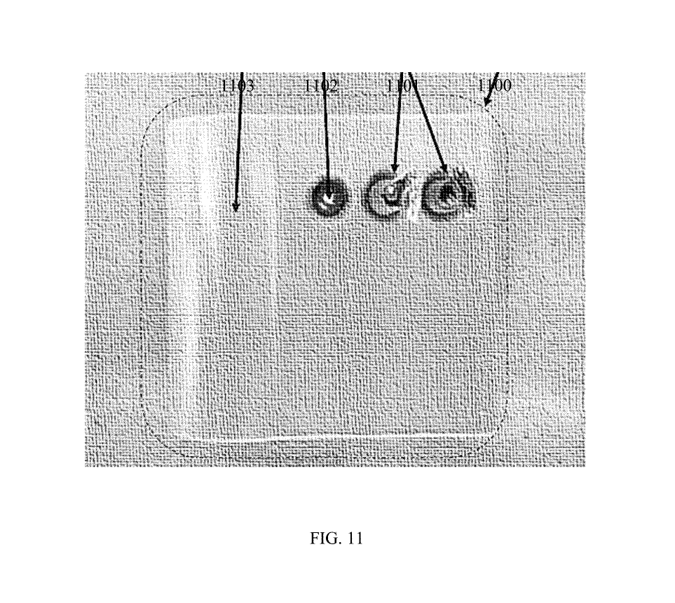

A LED is used for monitoring the battery strength and the digital signal function shown in 1102. The complete module is setup in a small shell or case with respective outputs shown in the region 1100 of FIG. 11 The specifications of the module are depicted to have a standard pyroelectric signal which acts as two phase output signal shown in the region of 1101 having two metal conductors. Peak of the phase voltages are referenced with the common ground of the voltage booster circuit that is required to boost at least to the voltage of a single rechargeable battery (1.25V-1.4V). The button cell battery compartment is shown in 1103.

Results of the Pocket Pyroelectric Electronic Module

Results are shown in FIG. 12. Data is presented in the region of 120. It indicates that the module was working at 4.7 Hz and the analog pyroelectric output was about 0.63V rms and 0.94V peak at no-load condition.

Applications of the Electronic Pyroelectric Device Module

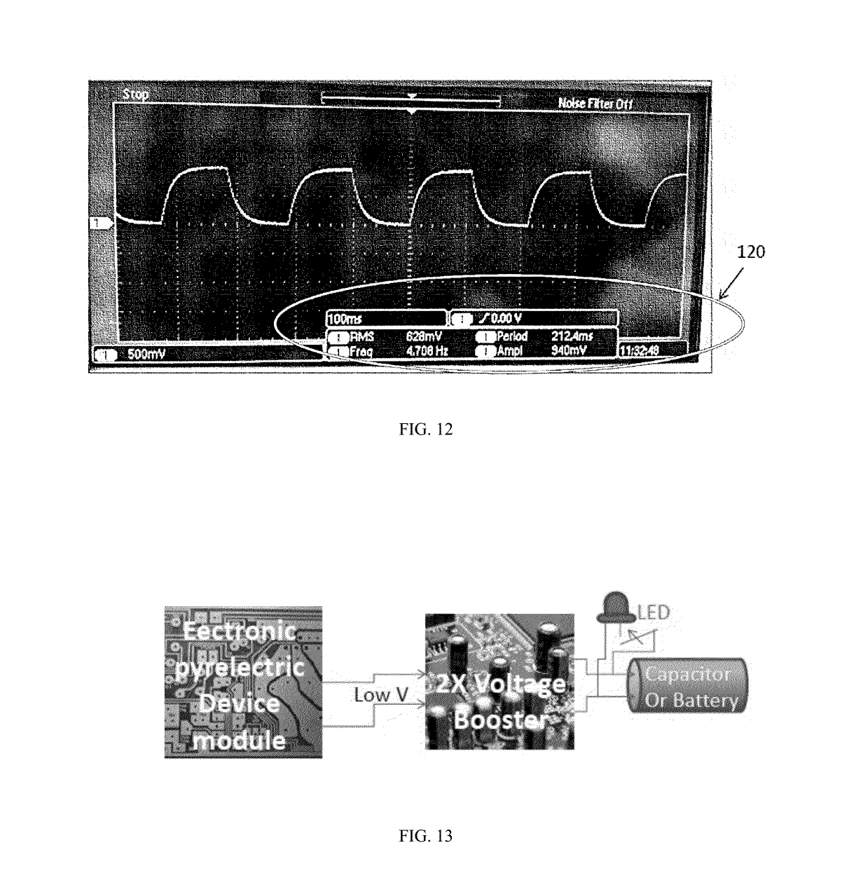

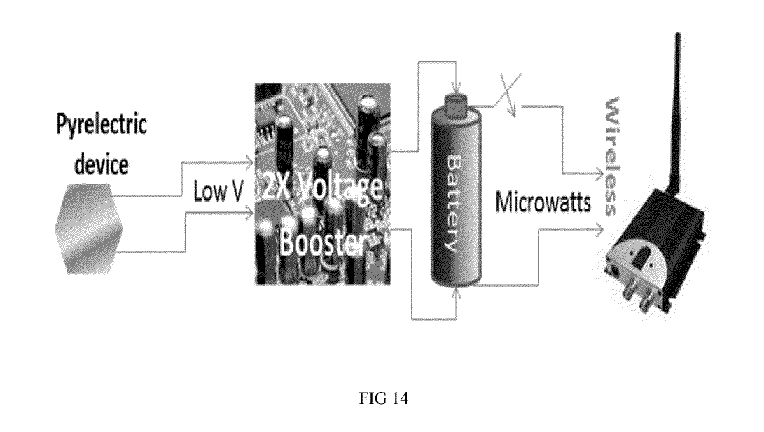

FIG. 13 and FIG. 14 shows effective applications of the pyroelectric reference device and its setup. An electronic boost converter was used to convert pyroelectric voltage to about two times, so a battery can be charged.

Results and Applications of the Electronic Pyroelectric Module

Two button cell alkaline batteries, A76 and SR626 batteries were discharged about 25% below their available voltage (about 1.2V) and then recharged back to 1.45V in 20 and 4.5 hours, respectively. It was shown that these batteries could be used in small power transmitters and watch circuitry. Also micro- and nano-power pyroelectric devices are great applications in the implanted medical devices.

Efficiency of the Electronic Pyroelectric Device Module Under Electrical Tests

Efficiency of pyroelectric device output with 2× boost converter under load condition of a charging device (1000 uF capacitor). Average values of the repeated test values from pocket pyroelectric module with the decaying supply power of batteries, are given in the Table 1. The pyroelectric module with 2× boost converter generated voltage high enough to recharge a small battery indicated in the region of 520.

TABLE 1
Efficiency of the pocket pyroelectric device module

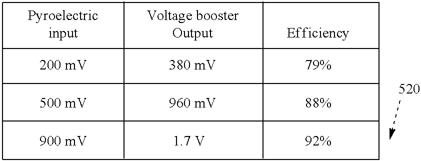

An embodiment for PSPICE based simulations for pyroelectric equivalent circuits were structured to implement improvements to get the best possible output taking into considerations of a standard lithium tantalite pyroelectric material. The device was then tested with the breadboard setup. Once verification of performance is complete, actual soldering of the complete circuit is finalized. PSPICE scripts are developed for each and every model in the circuit and developed in the hardware to complete the device as an ultra compact portable module for pyroelectric device.

Several facts of low-input-voltage boost converter designs were tested to verify the pyroelectronic reference device/module. The entire system is modeled onto a single PCB. The results of operating voltage and current values confirm that it is applicable for both Pyroelectric device and pyroelectric sensor purposes.

In brief, the present invention relates to a device and method of use to provide for an electronic equivalent circuit and hardware module that produces similar electrical characteristics of a pyroelectric material sample device.

The disclosed device and method of use is generally described, with examples incorporated as particular embodiments of the invention and to demonstrate the practice and advantages thereof. It is understood that the examples are given by way of illustration and are not intended to limit the specification or the claims in any manner.

To facilitate the understanding of this invention, a number of terms may be defined below. Terms defined herein have meanings as commonly understood by a person of ordinary skill in the areas relevant to the present invention. Terms such as “a”, “an”, and “the” are not intended to refer to only a singular entity, but include the general class of which a specific example may be used for illustration. The terminology herein is used to describe specific embodiments of the invention, but their usage does not delimit the disclosed device or method, except as may be outlined in the claims. Consequently, any embodiments comprising a one piece or multi piece device having the structures as herein disclosed with similar function shall fall into the coverage of claims of the present invention and shall lack the novelty and inventive step criteria.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific device and method of use described herein. Such equivalents are considered to be within the scope of this invention and are covered by the claims.

All publications, references, patents, and patent applications mentioned in the specification are indicative of the level of those skilled in the art to which this invention pertains. All publications, references, patents, and patent application are herein incorporated by reference to the same extent as if each individual publication, reference, patent, or patent application was specifically and individually indicated to be incorporated by reference.

In the claims, all transitional phrases such as “comprising,” “including,” “carrying,” “having,” “containing,” “involving,” and the like are to be understood to be open-ended, i.e., to mean including but not limited to. Only the transitional phrases “consisting of” and “consisting essentially of,” respectively, shall be closed or semi-closed transitional phrases.

The device and/or methods disclosed and claimed herein can be made and executed without undue experimentation in light of the present disclosure. While the device and methods of this invention have been described in terms of preferred embodiments, it will be apparent to those skilled in the art that variations may be applied to the device and/or methods and in the steps or in the sequence of steps of the method described herein without departing from the concept, spirit, and scope of the invention.

More specifically, it will be apparent that certain components, which are both shape and material related, may be substituted for the components described herein while the same or similar results would be achieved. All such similar substitutes and modifications apparent to those skilled in the art are deemed to be within the spirit, scope, and concept of the invention as defined by the appended claims.

### REFERENCES

1. J. Xie, P. P. Mane & K. L. Kam, “Energy harvesting by pyroelectric effect using PZT,” Asme Conf Smart Materials, Adaptive Intelligent Syst., vol. SMASIS 2008-605, p. 2, October 2008.
2. A. Odon, &, “Modelling and simulation of the pyroelectric detector using MATLAB/Simulink,” Measurement Science Rev., vol. 10, no. 6, p. 3, 2010.
3. K. A. Batra & A. Bhalla, “Simulation of energy harvesting from roads via pyroelectricity,” J. Photonics for Energy, vol. 1, p. 1, 2011.
4. S. Efftoymiou & K. B. Ozanyan, “Pulsed performance of pyroelectric detectors,” J. Physics, vol. 178 012044, p. 3, 2009.
5. http://www.gdp.if.pwr.wroc.pl/pliki/pyroelectric-effect.pdf
6. http://en.wikipedia.org/wiki/Pyroelectricity
7. K. I. Hwu & Y. H. Chen, “A novel voltage boosting converter with passive voltage clamping,” Icset, 2008.
8. S. B lang, “pyroelectricity: from ancient curiosity to modern imaging tool”, Physics today, (2005).
9. B. Brewster, “observations on the pyroelectricity of minerals”, Edindsburgh. J. Sci, I (1824), 208-215.
10. M. R Srinivasan, “pyroelectric materials”, Bull mater. Sci 6 (1984) 317-325.
11. V. Danvien “Numerical and experimental study of a pyroelectric energy converter for harvesting waste heat” University of California, Los angles, 2008.
12. W. Yaw Chung, S. Tai-ping & Y. Kaw, “design of pyroelectric read-out circuitry based on Lita03 detectors.” IEEE, vol. 96, March 1996.
13. Laser components “Infra Tec”, detectors basics, pyroelectricity library.
14. W. P. Wheless, J. A. Wells &, “An equivalent-circuit radiation sensor model,” IEEE-dept Elect. Eng-university Alabama, vol. 94, March 1994.

What is claimed is:

1. A pyroelectric reference device comprising:
an electronic equivalent circuit that produces similar characteristics of a pyroelectric material sample device.

2. The device of claim 1, wherein said equivalent circuit is comprised of a pulse generator and a signal conditioning circuit configured to match the electrical characteristics of a particular type of pyroelectric material device.

3. The device of claim 2, wherein the signal conditioning circuit is a charge compensation circuit.

4. The device of claim 1, wherein the electronic equivalent circuit's signal information is converted through read-out circuitry.

5. The device of claim 4, wherein said read-out circuitry is comprised of a source follower with integrated gain stage.

6. The device of claim 5, wherein said read-out circuit is further comprised of a pre-amplifier with high impedence input.

7. The device of claim 4, wherein said source follower with integrated gain stage is a combination of both a voltage mode follower and a current mode amplifier.

8. The device of claim 7, wherein said read-out circuit is further comprised of a pre-amplifier with high impedence input.

9. The device of claim 8, wherein said electronic equivalent circuit is further comprised of a twin channel pyroelectric element with two load resistors, two FET's, and two source resistors.

10. The device of claim 5, wherein the electronic equivalent circuit is further comprised of very low threshold voltage FET switches that operate with complementary trigger signals.

11. The device of claim 10, wherein the control through the circuit is maintained through the gate of switches.

12. The device of claim 11, wherein the capacitor is charged with one switch and the capacitor is discharged with another switch.

13. The device of claim 9, wherein said source resistors are modeled at a very high electrical resistance.

14. The device of claim 1, wherein the electronic equivalent circuit is modeled onto a single printed circuit board.

15. A pyroelectric reference device comprising:
an electronic equivalent circuit that produces similar characteristics of a pyroelectric material sample device;
said electronic equivalent circuit is comprised of two parts;
wherein said first part is comprised of a pulse generator and digital input/output;
and wherein said second part are signal conditioning circuit components.

16. The device of claim 15, wherein part one is further comprised of a current push pull amplifier and peak voltage monitoring.

17. The device of claim 15, wherein the signal conditioning circuit components is comprised of a charge compensation circuit as well as a duty cycle control for both digital and analog signals.

18. The device of claim 15, further comprising a digital LED for visual monitoring.

19. The device of claim 15, wherein the pulse generator circuit is comprised of two comparator amps.

20. The device of claim 15, wherein the electronic equivalent circuit is modeled onto a single printed circuit board.
